(19) United States
(12) Patent Application Publication
(10) Pub. No.: US 2024/0055459 A1
(43) Pub. Date: Feb. 15, 2024

(54) SEMICONDUCTOR DEVICE AND FABRICATION METHOD THEREFOR

(71) Applicant: WUHAN XINXIN SEMICONDUCTOR MANUFACTURING CO., LTD., Wuhan (CN)

(72) Inventors: Fan YANG, Wuhan (CN); Sheng HU, Wuhan (CN); Beibei SHENG, Wuhan (CN)

(21) Appl. No.: 18/259,766

(22) PCT Filed: Oct. 14, 2021
(86) PCT No.: PCT/CN2021/123711

§ 371 Date: Jun. 28, 2023

(30) Foreign Application Priority Data
Jun. 9, 2021 (CN) 202110642170.X

(51) Int. Cl. H01L 27/146

(52) U.S. Cl. CPC H01L 27/1463; H01L 27/14632; H01L 27/14687

(57) ABSTRACT

A semiconductor device includes a first wafer; a trench isolation ring formed in the first wafer and comprising a first metal layer; a first insulating dielectric layer formed on a surface of the first wafer, including at least one first through hole and at least one second through hole formed therein, the first through hole exposing a surface of the first metal layer, the second through hole exposing the surface of the first wafer; a barrier layer formed at least on the surface of the first wafer exposed in the second through hole; and a second metal layer formed on the first insulating dielectric layer so as to fill up the first and second through holes. The semiconductor device circumvent increased contact resistance, possible aluminum spiking and other problems. The method exhibits improved robustness and imparts higher performance to a semiconductor device fabricated using the method.

### TECHNICAL FIELD

The present invention relates to the field of semiconductor integrated circuit fabrication and, in particular, to a semiconductor device and a method of fabricating the device.

### BACKGROUND

For semiconductor technology, it is often necessary to apply a voltage to a semiconductor device. For example, existing backside-illuminated CMOS image sensors (BSI-CIS's) and depth sensors requires a high bias voltage for their normal operation. In order to apply a bias voltage to a photosensitive device from its backside, the bias voltage may be applied to a metal pad and then transferred to a silicon substrate through a backside metal grid (BMG) layer and a backside metal via (BMV) structure so that a bias voltage is present across the whole device.

For example, such a BMG layer and BMV structures may be conventionally formed using a process including the steps of:
first bonding a device wafer to a carrier wafer;
then thinning a silicon substrate of the device wafer from its backside;
next, forming a deep trench in the silicon substrate from the backside of the device wafer, successively forming an insulating material layer and a first barrier layer over inner surfaces of the deep trench, and filling a first metal layer in the deep trench, thereby forming a trench isolation ring in the deep trench;
subsequently, forming a buffer oxide layer over the backside of the device wafer and etching the buffer oxide layer to form through holes therein, which expose both the trench isolation ring and part of a top surface of the silicon substrate around the trench isolation ring;
afterwards, forming a second barrier layer over inner surfaces of the through holes and forming a second metal layer over the buffer oxide layer so that the second metal layer fills up the through holes; and
thereafter, etching the second metal layer residing on a top surface of the buffer oxide layer, thereby forming the BMG layer on the top surface of the buffer oxide layer and the BMV structures in the through hole. FIGS. 1a to 1c show an exemplary arrangement of the conventional through holes that expose both the silicon substrate and the trench isolation ring. As can be seen from FIGS. 1a and 1b, the trench isolation ring 13 is rectangular and the BMV structures 14 are formed in the through holes (not shown) that are so formed in the buffer oxide layer 12 at the respective corners of the trench isolation ring 13 so as to each expose both the trench isolation ring 13 and part of the top surface of the silicon substrate 11 around the trench isolation ring 13. The BMG layer 15 resides on top surfaces of the BMV structures 14. As can be seen from FIGS. 1a and 1c, there are no through holes formed in the buffer oxide layer 12 along the sides of the rectangular trench isolation ring 13, and the BMG layer 15 is directly formed on the buffer oxide layer 12 over the trench isolation ring 13.

In the above-described step, etching the buffer oxide layer and thereby forming therein the through holes each exposing both the trench isolation ring and part of the top surface of the silicon substrate around the trench isolation ring requires a very complicated process. In order to completely remove the buffer oxide layer above the trench isolation ring portions and top surface of portions of the silicon substrate to be exposed, an over-etching process is generally employed to also remove small portions of the silicon substrate and trench isolation ring underlying the buffer oxide layer. Since the silicon substrate and trench isolation ring are made of materials including silicon, insulating and metal materials, the over-etching process will proceed at significantly differing etching rates. Consequently, bottom surfaces of the resulting through holes have high morphological inconsistency, which will cause the problems as follows, during the subsequent formation of the second barrier layer.

1) When the over-etching process is a dry etching process, an exposed first metal material layer will also be bombarded, sputtering the metal from the first metal material layer onto the “clean” surface of the silicon substrate. Due to the presence of this layer of the sputtered metal on the silicon substrate surface, after the second barrier layer is formed, it is not in direct contact with the silicon substrate and thus cannot react therewith (e.g., in case of the second barrier layer being a Ti layer, Ti therein will not contact and react with Si to form TiSi₂), leading to significant contact resistance at the locations where the BMV structures come into contact with the silicon substrate.

2) Due to the significant morphological inconsistency (non-flatness) of the bottom surfaces of the through holes, it is difficult to achieve continuity of the second barrier layer over the bottom surfaces of the through holes. Any crack or other defect in the second barrier layer will destroy its ability to block fusion of the second metal layer with the silicon substrate. In particular, aluminum (Al) spiking may occur in severe cases when the second metal layer is an Al layer.

Therefore, there is an urgent need to improve the above conventional semiconductor device structure and method of fabrication to solve their problems of high contact resistance and possible aluminum spiking.

### SUMMARY OF THE INVENTION

It is an objective of the present invention to provide a semiconductor device and a method of fabricating it, which circumvents the problems of increased contact resistance, possible aluminum spiking and the like. The method exhibits improved robustness and imparts higher performance to a semiconductor device fabricated using the method.

To this end, the present invention provides a semiconductor device including:
a first wafer;
a trench isolation ring formed in the first wafer, the trench isolation ring including a first metal layer;
a first insulating dielectric layer formed on a surface of the first wafer, the first insulating dielectric layer having at least one first through hole and at least one second through hole formed therein, the first through hole exposing a surface of the first metal layer, the second through hole exposing the surface of the first wafer;
a barrier layer formed at least on the surface of the first wafer exposed in the second through hole; and
a second metal layer formed on the first insulating dielectric layer so as to fill up the first and second through holes.

Optionally, the first wafer may include a substrate and a device layer formed on the substrate, wherein the trench isolation ring is formed in the substrate on a backside of the first wafer, and the first insulating dielectric layer is formed on a backside of the substrate.

Optionally, the trench isolation ring may further include a second insulating dielectric layer formed on side and bottom surfaces of a ring-shaped trench in the first wafer, which is filled up by the first metal layer.

Optionally, the trench isolation ring may have a rectangular, hexagonal or octagonal transverse cross-section.

Optionally, the first through hole may be located above a side and/or a corner of the trench isolation ring, and the second through hole may be located above the first wafer at a location closer to a side and/or a corner of the trench isolation ring.

Optionally, the semiconductor device may further include a second wafer bonded to the first wafer.

The present invention also provides a method of fabricating a semiconductor device, which includes:
providing a first wafer;
forming a trench isolation ring in the first wafer, the trench isolation ring including a first metal layer;
forming a first insulating dielectric layer on a surface of the first wafer, the first insulating dielectric layer having at least one first through hole and at least one second through hole formed therein, the first through hole exposing a surface of the first metal layer, the second through hole exposing the surface of the first wafer;
forming a barrier layer at least on the surface of the first wafer exposed in the second through hole; and
forming a second metal layer on the first insulating dielectric layer so that the second metal layer fills up the first and second through holes.

Optionally, the first wafer may include a substrate and a device layer formed on the substrate, wherein the trench isolation ring is formed in the substrate on a backside of the first wafer, and the first insulating dielectric layer is formed on a backside of the substrate.

Optionally, the trench isolation ring may have a rectangular, hexagonal or octagonal transverse cross-section.

Optionally, the first through hole may be located above a side and/or a corner of the trench isolation ring, and the second through hole may be located above the first wafer at a location closer to a side and/or a corner of the trench isolation ring.

Optionally, the method may further include, prior to the formation of the barrier layer at least on the surface of the first wafer exposed in the second through hole, removing oxide on the surface of the first wafer exposed in the second through hole by performing a sputtering process thereon.

Optionally, before the trench isolation ring is formed in the first wafer, bonding layers may be formed respectively on surface of the first wafer and a second wafer, and the first wafer may be bonded to the second wafer through the bonding layers.

Compared with the prior art, the present invention offers the benefits as follows:

1. In the semiconductor device of the present invention, since the through holes in the first insulating dielectric layer are designed as the first and second through holes that separately expose the surface of the first metal layer in the trench isolation ring and the surface of the first wafer, respectively, during a dry etching process for etching the first insulating dielectric layer to form the first and second through holes therein, the metal material from the first metal layer can be prevented from sputtering onto the surface of the first wafer exposed in the second through hole, avoiding the presence of increased contact resistance between the second metal layer and the first wafer. Moreover, when the first insulating dielectric layer is over-etched and the underlying structures is also slightly etched away, the problem of significant morphological inconsistency of the bottom surfaces of the first and second through holes resulting from greatly differing etching rates can be avoided. Accordingly, the occurrence of aluminum spiking can be prevented, resulting in improved performance of the semiconductor device.

2. In the method of the present invention, since the through holes in the first insulating dielectric layer are designed as the first and second through holes that separately expose the surface of the first metal layer in the trench isolation ring and the surface of the first wafer, respectively, during a dry etching process for etching the first insulating dielectric layer to form the first and second through holes therein, the metal material from the first metal layer can be prevented from sputtering onto the surface of the first wafer exposed in the second through hole, avoiding the presence of increased contact resistance between the second metal layer and the first wafer. Moreover, when the first insulating dielectric layer is over-etched and the underlying structures is also slightly etched away, the problem of significant morphological inconsistency of the bottom surfaces of the first and second through holes resulting from greatly differing etching rates can be avoided. Accordingly, the occurrence of aluminum spiking can be prevented, resulting in increased robustness of the method and improved performance of a semiconductor device fabricated using the method.

### BRIEF DESCRIPTION OF THE DRAWINGS

FIG. 1a is a schematic top view of a conventional arrangement of through holes each exposing both a silicon substrate and a trench isolation ring.

FIG. 1b is a schematic longitudinal cross-sectional view of the arrangement of through holes each exposing both the silicon substrate and the trench isolation ring of FIG. 1a along line A-A′.

FIG. 1c is a schematic longitudinal cross-sectional view of the arrangement of through holes each exposing both the silicon substrate and the trench isolation ring of FIG. 1a along line B-B′.

FIG. 2 is a schematic top view of a semiconductor device according to an embodiment of the present invention.

FIG. 3 is a longitudinal cross-sectional view of the semiconductor device of FIG. 2 taken along line C-C′.

FIG. 4 is a longitudinal cross-sectional view of the semiconductor device of FIG. 2 taken along line D-D′.

FIG. 5 is a flowchart of a method of fabricating a semiconductor device according to an embodiment of the present invention.

FIGS. 6a to 6h are schematic illustrations of the semiconductor device being fabricated in the method of FIG. 5.

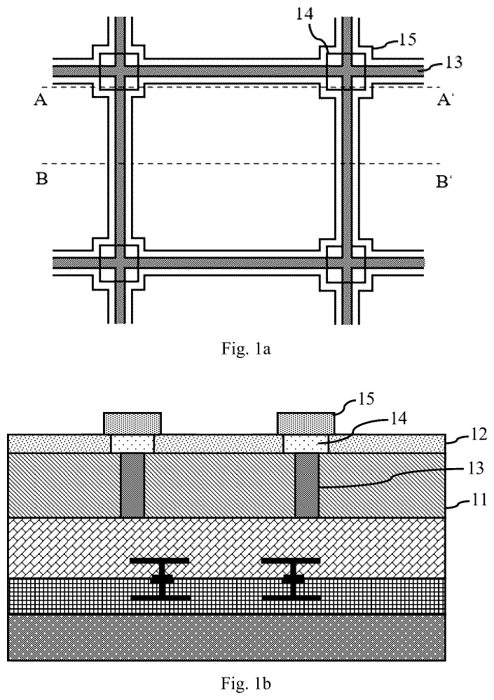

In FIGS. 1a to 6h:
11—silicon substrate; 12—buffer oxide layer; 13—trench isolation ring; 14—BMV structure; 15—BMG layer; 21—first wafer; 211—first substrate; 212—first device layer; 2121—first metal interconnection structure; 22—trench isolation ring; 221—second insulating dielectric layer; 222—first metal layer; 23—first insulating dielectric layer; 231—first through hole; 232—second through hole; 24—barrier layer; 25—second metal layer; 251—BMV structure; 252—BMG layer; 31—second wafer; 311—second substrate; 312—second device layer; 3121—second metal interconnection structure.

### DETAILED DESCRIPTION

Objectives, advantages and features of the present invention will become more apparent upon reading the following more detailed description of semiconductor devices and methods proposed in the present invention. Note that the figures are provided in a very simplified form not necessarily drawn to exact scale and for the only purpose of facilitating easy and clear description of the embodiments. Herein, the term “and/or” is used in the sense of “either or both of”.

In an embodiment of the present invention, there is provided a semiconductor device including a first wafer, a trench isolation ring, a first insulating dielectric layer, a barrier layer and a second metal layer. The trench isolation ring is formed in the first wafer and includes a first metal layer. The first insulating dielectric layer is formed on a surface of the first wafer, and at least one first through hole and at least one second through hole are formed in the first insulating dielectric layer. The first through hole exposes a surface of the first metal layer, and the second through hole exposes the surface of the first wafer. The barrier layer is formed at least on the surface of the first wafer exposed in the second through hole. The second metal layer is formed on the first insulating dielectric layer so as to fill up the first and second through holes.

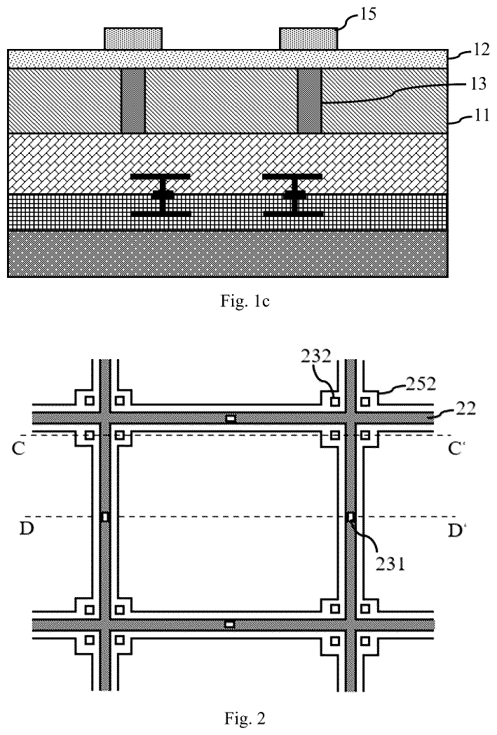

The semiconductor device provided in this embodiment may be, for example, an image sensor incorporating a three-dimensional (3D) integrated circuit (IC), and will be described in detail below with reference to FIGS. 2, 3 and 4. However, the present invention is not so limited and may be applied to processes for fabricating other structures requiring the application of a voltage.

The first wafer 21 includes a substrate and a device layer formed on the substrate (in order to be distinguished from a substrate and device layer of a second wafer 31, the substrate and device layer of the first wafer 21 are referred to as a first substrate 211 and a first device layer 212, respectively). In the first device layer 212, first metal interconnection structures 2121 are formed, as well as optionally, other functional structures, such as pixel arrays, transistors or MEMS microstructures (e.g., diaphragms, electrodes, etc.) are formed.

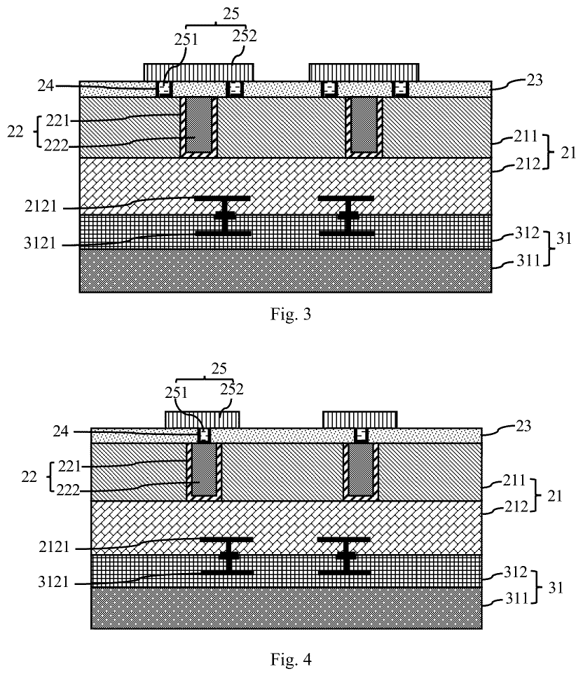

The first wafer 21 may be a device wafer, such as a pixel wafer containing a pixel array for an image sensor. The type of the first wafer 21 depends on the intended functionality of the device being fabricated. The first wafer 21 may be a single-layer wafer or consist of multiple wafers that are bonded together. FIGS. 3 and 4 show an example in which the first wafer 21 is a single-layer wafer.

In other embodiments, a second wafer 31 may be also provided, including a second substrate 311 and a second device layer 312 formed on the second substrate 311. A first bonding layer (not shown) may be formed on the first device layer 212 on the first wafer 21, and a second bonding layer (not shown) may be formed on the second device layer 312 on the second wafer 31. The first wafer 21 and the second wafer 31 may be then bonded together by the first and second bonding layers.

After the first wafer 21 is bonded to the second wafer 31, the first substrate 211 of the first wafer 21 may be thinned from the backside until the first substrate 211 of the first wafer 21 has a desired thickness.

The second wafer 31 may be a logic wafer containing CMOS circuits, and the second device layer 312 may contain MOS transistors, resistors, capacitors, second metal interconnection structures 3121 and the like. The second metal interconnection structures 3121 are electrically connected to the first metal interconnection structures 2121. The second wafer 31 may be a single-layer wafer or consist of multiple wafers that are bonded together. Alternatively, the second wafer 31 may be a carrier wafer without device functions. In this case, the second device layer 312 may be omitted from the second wafer 31, and the second bonding layer for bonding to the first bonding layer on the first wafer 21 may be instead directly formed thereon.

The trench isolation ring 22 is formed in the first wafer 21, and the trench isolation ring 22 includes a first metal layer 222.

The trench isolation ring 22 further includes a second insulating dielectric layer 221, the second insulating dielectric layer 221 is formed over side and bottom surfaces of a ring-shaped trench (not shown) in the first wafer 21, and the first metal layer 222 fills up the ring-shaped trench. Between the first metal layer 222 and the second insulating dielectric layer 221, a barrier layer (not shown) may be sandwiched for blocking metal material diffusion from the first metal layer 222.

In this embodiment, the trench isolation ring 22 is formed in the first substrate 211 on the backside of the first wafer 21. A shallow trench isolation (STI) structure (not shown) is formed in the first substrate 211, and the trench isolation ring 22 contacts the STI structure on its side proximal to the first device layer 212. Alternatively, the trench isolation ring 22 may extend through the first substrate 211 so that the side of the trench isolation ring 22 proximal to the first device layer 212 comes into contact with the first device layer 212.

In other embodiments, the trench isolation ring 22 may be formed in the first device layer 212 on the first wafer 21. In this case, the trench isolation ring 22 may extend over part of the thickness of the first device layer 212. Alternatively, the trench isolation ring 22 may extend through the first device layer 212 and come into contact with the first substrate 211.

In addition, a top surface of the trench isolation ring 22 may be flush with or raised over a surface of the first wafer 21. In the example shown in FIGS. 3 and 4, the top surface of the trench isolation ring 22 is flush with the backside of the first substrate 211 (i.e., the surface of the first substrate 211 distal from the first device layer 212). Alternatively, the top surface of the trench isolation ring 22 may be raised over the backside of the first substrate 211, and the second insulating dielectric layer 221 may be also formed on the backside of the first substrate 211.

Further, the first wafer 21 may define a device region and a pad region surrounding the device region. The trench isolation ring 22 may be formed in the device region and/or the pad region. If the trench isolation ring 22 is formed in the device region, then the trench isolation ring 22 encircles a portion of the first wafer 21, which forms an individual pixel element. There may be an array of such pixel elements in the device region of the first wafer 21, each pixel element is surrounded by a respective isolation ring 22.

The trench isolation ring 22 has a rectangular, hexagonal, octagonal or otherwise-shaped transverse cross-section. FIG. 2 schematically illustrates a complete trench isolation ring 22 with a square transverse cross-section, the square trench isolation ring 22 encircles a pixel element. The trench isolation ring 22 extends to the periphery along the extension direction of each side length to define a multiple square array structure.

The first insulating dielectric layer 23 is formed on a surface of the first wafer 21, and the at least one first through hole 231 and the at least one second through hole 232 are formed in the first insulating dielectric layer 23. The first through hole 231 exposes a surface of the first metal layer 222, and the second through hole 232 exposes the surface of the first wafer 21. The rest of the surface of the first wafer 21 may be covered by the first insulating dielectric layer 23.

In this embodiment, the first insulating dielectric layer 23 is formed on the backside of the first substrate 211, wherein the first through hole 231 exposes the surface of the first metal layer 222, and the second through hole 232 exposes the backside of the first substrate 211.

Moreover, when the second insulating dielectric layer 221 is also formed on the backside of the first substrate 211, the first insulating dielectric layer 23 covers the second insulating dielectric layer 221, and the second through hole 232 is formed in the second insulating dielectric layer 221 and the first insulating dielectric layer 23 on the backside of the first substrate 211.

In addition, the first through hole 231 may further expose a surface portion of the second insulating dielectric layer 221 around the first metal layer 222.

The first through hole 231 may be located on a side or a corner of the trench isolation ring 22, or the first through hole may be located on both of a side and a corner of the trench isolation ring 22. The second through hole 232 is located on the first wafer 21 at a location closer to a side or a corner of the trench isolation ring 22, or the second through hole is located on the first wafer 21 at a location closer to both of a side and a corner of the trench isolation ring 22.

In the example of FIG. 2, the first through holes 231 are located only on the respective sides of the square trench isolation ring 22, and the second through holes 232 are located only on the first substrate 211 at locations close to the respective corners of the square trench isolation ring 22.

The first through hole 231 and the second through hole 232 may have any suitable shape, such as rectangular, circular, etc.

Each of the first insulating dielectric layer 23 and the second insulating dielectric layer 221 is made of a material including at least one of silicon oxide and a high-k dielectric with a dielectric constant k greater than 3.9. Each of the first insulating dielectric layer 23 and the second insulating dielectric layer 221 may be a single-layer structure or a stack of at least two layers (e.g., one silicon oxide layer and one high-k dielectric layer).

The barrier layer 24 is formed at least on the surface of the first wafer 21 exposed in the second through hole 232, so that the subsequently-formed second metal layer 25 separates from at least the first wafer 21 via the barrier layer 24. The barrier layer 24 is formed to block metal diffusion from the second metal layer 25 into the first wafer 21.

In this embodiment, as the second through hole 232 exposes the backside of the first substrate 211, the barrier layer 24 is formed at least on the backside of the first substrate 211, so that the subsequently-formed second metal layer 25 at least separates from the first substrate 211 by the barrier layer 24.

The barrier layer 24 may be formed also on a side surface of the second through hole 232 and inner surfaces of the first through hole 231.

The second metal layer 25 is formed on the first insulating dielectric layer 23, the second metal layer 25 fills up the first through hole 231 and the second through hole 232. The second metal layer 25 residing in the first through hole 231 and the second through hole 232 can provide backside metal via (BMV) structures 251. The second metal layer 25 located above a top surface of the first insulating dielectric layer 23 can provide a backside metal grid (BMG) layer 252.

As shown in FIG. 2, the BMG layer 252 may have a transverse cross-sectional shape matching that of the trench isolation ring 22, the BMG layer 252 cover the trench isolation ring 22, the first through holes 231 and the second through holes 232.

The barrier layer 24 may be formed of a material including at least one of titanium, tantalum and a metal nitride (e.g., titanium nitride, tantalum nitride, tungsten nitride or the like). Each of the first metal layer 222 and the second metal layer 25 may be formed of at least one of tungsten, aluminum, copper, silver, gold and other metals.

Further, the first wafer 21 includes the pad region surrounding the device region, via plugs (not shown) may be formed in the first wafer 21 in the pad region. A pad structure (not shown) may be formed on top of each via plug, a bias voltage can be applied from the pad structure, and then the bias voltage can be fed into the first substrate 211 by the BMG layer 252, resulting in a bias voltage present across the whole semiconductor device.

As can be seen from the above description of the semiconductor device, since the through holes in the first insulating dielectric layer are designed as a combination of the first and second through holes that separately expose the surface of the first metal layer in the trench isolation ring and the surface of the first wafer, respectively, even when the first metal layer is bombarded during a dry etching process for etching the first insulating dielectric layer to form the first and second through holes therein, blocked by the first insulating dielectric layer present between the first and second through holes, the metal material from the first metal layer (e.g., metal W) can be prevented from sputtering onto the surface of the first wafer exposed in the second through hole. This allows the barrier layer to come into direct contact with the first wafer exposed in the second through hole, avoiding the presence of increased contact resistance between the second metal layer and the first wafer (in this embodiment, between the BMV structures and the first substrate). Additionally, in the dry etching process performed on the first insulating dielectric layer for forming the first and second through holes, as the first through hole exposes only the first metal layer, and since the second through hole exposes only the first wafer, the bottom surfaces of the first and second through holes are both provided by single materials. In this way, when the first insulating dielectric layer is over-etched and the underlying structures is also slightly etched away, the problem of significant morphological inconsistency of the bottom surfaces of the first and second through holes resulting from greatly differing etching rates can be avoided. This allows the barrier layer to be continuous (without cracks or other defects) and thus have the ability to block fusion of the second metal layer with the first substrate, avoiding the occurrence of aluminum spiking in the case of the second metal layer being made of aluminum (Al). Further, the barrier layer is allowed to have a reduced thickness, which imparts lower contact resistance and can reduce cost. Furthermore, the occurrence of aluminum spiking can be avoided when an alloying process is employed after the formation of the second metal layer for removing any defect in the second metal layer.

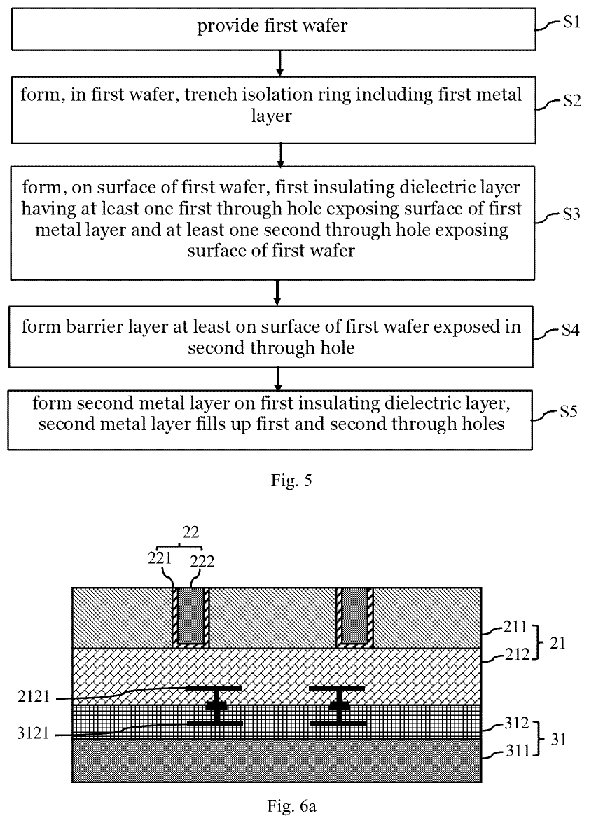

In an embodiment of the present invention, there is provided a method of fabricating a semiconductor device. As shown in FIG. 5, FIG. 5 shows a flowchart of a method of fabricating a semiconductor device according to of fabricating a semiconductor device. As shown, the method of fabricating a semiconductor device includes the steps of:
Step S1: providing a first wafer;
Step S2: forming a trench isolation ring in the first wafer, the trench isolation ring including a first metal layer;
Step S3: forming a first insulating dielectric layer on a surface of the first wafer, the first insulating dielectric layer having at least one first through hole and at least one second through hole therein, the first through hole exposing a surface of the first metal layer, the second through hole exposing the surface of the first wafer;
Step S4: forming a barrier layer at least on the surface of the first wafer exposed in the second through hole; and
Step S5: forming a second metal layer on the first insulating dielectric layer so that the second metal layer fills up the first and second through holes.

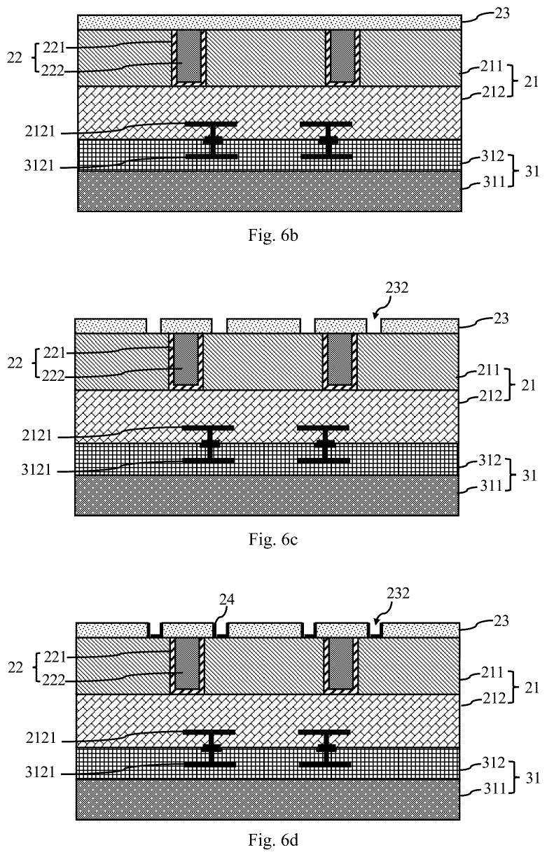

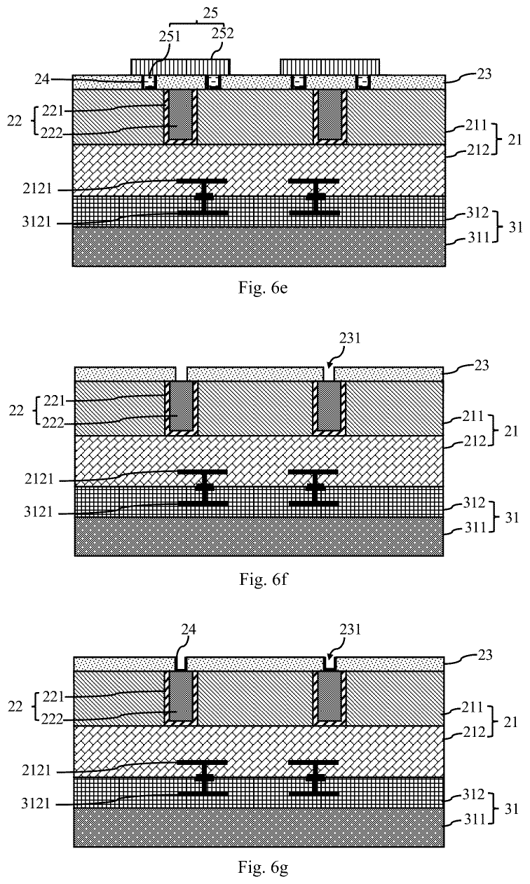

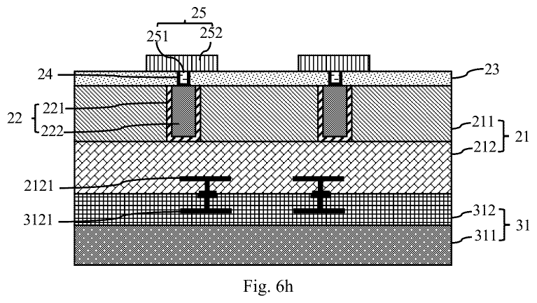

The method provided in this embodiment will be described in detail below with reference to FIGS. 2 and 6a to 6h in the context of an image sensor incorporating a three-dimensional (3D) integrated circuit (IC). FIGS. 6a to 6e are longitudinal cross-sectional views of the semiconductor device of FIG. 2 taken along line C-C′, and FIGS. 6f to 6h are longitudinal cross-sectional views of the semiconductor device of FIG. 2 taken along line D-D′. However, the present invention is not so limited, as it may also be applied to processes for fabricating other structures requiring the application of a voltage.

In step S1, referring to FIG. 6a, a first wafer 21 is provided.

The first wafer 21 includes a substrate and a device layer formed on the substrate (in order to be distinguished from a substrate and device layer of a second wafer 31, the substrate and device layer of the first wafer 21 are referred to as a first substrate 211 and a first device layer 212, respectively). In the first device layer 212, first metal interconnection structures 2121 are formed, as well as optionally, other functional structures, such as pixel arrays, transistors or MEMS microstructures (e.g., diaphragms, electrodes, etc.) are formed.

The first wafer 21 may be a device wafer, such as a pixel wafer containing a pixel array for an image sensor. The type of the first wafer 21 depends on the intended functionality of the device being fabricated. The first wafer 21 may be a single-layer wafer or consist of multiple wafers that are bonded together. FIG. 6a shows an example in which the first wafer 21 is a single-layer wafer.

In other embodiments, a second wafer 31 may be also provided, including a second substrate 311 and a second device layer 312 formed on the second substrate 311. A first bonding layer (not shown) may be formed on the first device layer 212 on the first wafer 21, and a second bonding layer (not shown) may be formed on the second device layer 312 on the second wafer 31. The first wafer 21 and the second wafer 31 may be then bonded together through the first and second bonding layers.

After the first wafer 21 is bonded to the second wafer 31, the first substrate 211 of the first wafer 21 may be thinned from the backside until the first substrate 211 of the first wafer 21 has a desired thickness.

The second wafer 31 may be a logic wafer containing CMOS circuits, and the second device layer 312 may contain MOS transistors, resistors, capacitors, second metal interconnection structures 3121 and the like. The second metal interconnection structures 3121 are electrically connected to the first metal interconnection structures 2121. The second wafer 31 may be a single-layer wafer or consist of multiple wafers that are bonded together. Alternatively, the second wafer 31 may be a carrier wafer without device functions. In this case, the second device layer 312 may be omitted from the second wafer 31, and the second bonding layer for bonding to the first bonding layer on the first wafer 21 may be instead directly formed thereon.

In step S2, referring to FIG. 6a, a trench isolation ring 22 is formed in the first wafer 21, and the trench isolation ring 22 includes a first metal layer 222.

The trench isolation ring 22 further includes a second insulating dielectric layer 221, the second insulating dielectric layer 221 is formed over side and bottom surfaces of a ring-shaped trench (not shown) in the first wafer 21, and the first metal layer 222 fills up the ring-shaped trench. Between the first metal layer 222 and the second insulating dielectric layer 221, a barrier layer (not shown) may be sandwiched for blocking metal material diffusion from the first metal layer 222.

In this embodiment, the trench isolation ring 22 is formed in the first substrate 211 on the backside of the first wafer 21. A shallow trench isolation (STI) structure (not shown) is formed in the first substrate 211, and the trench isolation ring 22 contacts the STI structure on its side proximal to the first device layer 212. Alternatively, the trench isolation ring 22 may extend through the first substrate 211 so that the side of the trench isolation ring 22 proximal to the first device layer 212 comes into contact with the first device layer 212.

In case of the trench isolation ring 22 extending through the first substrate 211, for example, the formation of the trench isolation ring 22 in the first wafer 21 may include the steps of: at first, etching the first substrate 211 to form the ring-shaped trench that extends through the first substrate 211; then forming the second insulating dielectric layer 221 over the inner surfaces of the ring-shaped trench and the backside of the first substrate 211; forming the first metal layer 222 that covers the second insulating dielectric layer 221 on the backside of the first substrate 211, the first metal layer 222 fills up the ring-shaped trench; and subsequently, etching the first metal layer 222 or performing a planarization process thereon to remove the first metal layer 222 above the second insulating dielectric layer 221 on the backside of the first substrate 211, wherein the second insulating dielectric layer 221 on the backside of the first substrate 211 may be either retained or removed.

In other embodiments, the trench isolation ring 22 may be formed in the first device layer 212 on the first wafer 21. In this case, the trench isolation ring 22 may extend over part of the thickness of the first device layer 212. Alternatively, the trench isolation ring 22 may extend through the first device layer 212 and come into contact with the first substrate 211.

In addition, a top surface of the trench isolation ring 22 may be flush with or raised over a surface of the first wafer 21. In the example shown in FIG. 6a, the top surface of the trench isolation ring 22 is flush with the backside of the first substrate 211 (i.e., the surface of the first substrate 211 distal from the first device layer 212). Alternatively, the top surface of the trench isolation ring 22 may be raised over the backside of the first substrate 211, and the second insulating dielectric layer 221 may be also formed on the backside of the first substrate 211.

Further, the first wafer 21 may define a device region and a pad region surrounding the device region. The trench isolation ring 22 may be formed in the device region and/or the pad region. If the trench isolation ring 22 is formed in the device region, then the trench isolation ring 22 encircles a portion of the first wafer 21, which forms an individual pixel element. There may be an array of such pixel elements in the device region of the first wafer 21, each pixel element is surrounded by a respective isolation ring 22.

The trench isolation ring 22 has a rectangular, hexagonal, octagonal or otherwise-shaped transverse cross-section. FIG. 2 schematically illustrates a complete trench isolation ring 22 with a square transverse cross-section, the square trench isolation ring 22 encircles a pixel element. The trench isolation ring 22 extends to the periphery along the extension direction of each side length to define a multiple square array structure.

The first metal layer 222 may be formed of at least one of tungsten, aluminum, copper, silver, gold and other metals.

In step S3, referring to FIGS. 6b, 6c and 6f, a first insulating dielectric layer 23 is formed on a surface of the first wafer 21. The at least one first through hole 231 and the at least one second through hole 232 are formed in the first insulating dielectric layer 23. The first through hole 231 exposes a surface of the first metal layer 222, and the second through hole 232 exposes the surface of the first wafer 21. The rest of the surface of the first wafer 21 may be covered by the first insulating dielectric layer 23.

The formation of the first through hole 231 and the second through hole 232 may include the steps of: first of all, as shown in FIG. 6b, forming the first insulating dielectric layer 23 over the backside of the first substrate 211 so that the first insulating dielectric layer 23 buries the trench isolation ring 22; and then, as shown in FIGS. 6c and 6f, performing a dry etching process on the first insulating dielectric layer 23 to form, in the first insulating dielectric layer 23, the first through hole 231 exposing the surface of the first metal layer 222 and the second through hole 232 exposing the backside of the first substrate 211.

When the second insulating dielectric layer 221 is also formed on the backside of the first substrate 211, the first insulating dielectric layer 23 covers the second insulating dielectric layer 221, and the second through hole 232 is formed in the second insulating dielectric layer 221 and the first insulating dielectric layer 23 on the backside of the first substrate 211.

In addition, the first through hole 231 may further expose a surface portion of the second insulating dielectric layer 221 around the first metal layer 222.

The first through hole 231 may be located on a side or a corner of the trench isolation ring 22, or the first through hole may be located on both of a side and a corner of the trench isolation ring 22. The second through hole 232 is located on the first wafer 21 at a location closer to a side or a corner of the trench isolation ring 22, or the second through hole is located on the first wafer 21 at a location closer to both of a side and a corner of the trench isolation ring 22.

In the example of FIG. 2, the first through holes 231 are located only on the respective sides of the square trench isolation ring 22, and the second through holes 232 are located only on the first substrate 211 at locations close to the respective corners of the square trench isolation ring 22.

The first through hole 231 and the second through hole 232 may have any suitable shape, such as rectangular, circular, etc.

Each of the first insulating dielectric layer 23 and the second insulating dielectric layer 221 is made of a material including at least one of silicon oxide and a high-k dielectric with a dielectric constant k greater than 3.9. Each of the first insulating dielectric layer 23 and the second insulating dielectric layer 221 may be a single-layer structure or a stack of at least two layers (e.g., one silicon oxide layer and one high-k dielectric layer).

In step S4, referring to FIGS. 6d and 6g, a barrier layer 24 is formed at least on the surface of the first wafer 21 exposed in the second through hole 232, so that the subsequently-formed second metal layer 25 separates from at least the first wafer 21 via the barrier layer 24. The barrier layer 24 is formed to block metal diffusion from the second metal layer 25 into the first wafer 21.

In the embodiment shown in FIGS. 6d and 6g, as the second through hole 232 exposes the backside of the first substrate 211, the barrier layer 24 is formed at least on the backside of the first substrate 211, so that the subsequently-formed second metal layer 25 at least separates from the first substrate 211 by the barrier layer 24.

The barrier layer 24 may be formed also on a side surface of the second through hole 232 and inner surfaces of the first through hole 231.

The barrier layer 24 may be formed of a material including at least one of titanium, tantalum and a metal nitride (e.g., titanium nitride, tantalum nitride, tungsten nitride or the like).

Before the barrier layer 24 is formed at least on the surface of the first wafer 21 exposed in the second through hole 232, the method may further include removing oxide on the surface of the first wafer 21 exposed in the second through hole 232 by performing a sputtering process thereon.

In this embodiment, the first substrate 211 on the backside of the first wafer 21 exposed in the second through hole 232 is prone to surface oxidation, and the resulting oxide on the surface is detrimental to direct contact of the subsequently-formed barrier layer 24 with the first substrate 211. Therefore, before the barrier layer 24 is formed, the surface of the first wafer 21 exposed in the second through hole 232 is pre-cleaned by sputtering (e.g., with Ar) to remove the oxide to expose the underlying material of the substrate 211.

In step S5, referring to FIGS. 6e and 6h, a second metal layer 25 is formed on the first insulating dielectric layer 23, the second metal layer 25 fills up the first through hole 231 and the second through hole 232.

A metal material may be deposited into the first through hole 231 and the second through hole 232 and over the first insulating dielectric layer 23, and the second metal layer 25 may be formed by etching the metal material above the first insulating dielectric layer 23. The second metal layer 25 residing in the first through hole 231 and the second through hole 232 can provide backside metal via (BMV) structures 251. The second metal layer 25 located above a top surface of the first insulating dielectric layer 23 can provide a backside metal grid (BMG) layer 252.

As shown in FIG. 2, the BMG layer 252 may have a transverse cross-sectional shape matching that of the trench isolation ring 22, the BMG layer 252 covers the trench isolation ring 22, the first through holes 231 and the second through holes 232.

The second metal layer 25 may be formed of at least one of tungsten, aluminum, copper, silver, gold and other metals.

An alloying process may be subsequently carried out to remove any possible defect in the second metal layer 25 and other components, as well as moisture in the semiconductor device.

Further, the method may further include forming via plugs (not shown) in the pad region surrounding the device region of the first wafer 21 and pad structures (not shown) on top of the respective via plugs. In this way, a bias voltage may be applied to a pad structure and then transferred into the first substrate 211 by the BMG layer 252, resulting in a bias voltage present across the whole semiconductor device.

As can be seen from the above description of steps S1 to S5, since the through holes in the first insulating dielectric layer are designed as a combination of the first and second through holes that separately expose the surface of the first metal layer in the trench isolation ring and the surface of the first wafer, respectively, even when the first metal layer is bombarded during a dry etching process for etching the first insulating dielectric layer to form the first and second through holes therein, blocked by the first insulating dielectric layer present between the first and second through holes, the metal material from the first metal layer (e.g., metal W) can be prevented from sputtering onto the surface of the first wafer exposed in the second through hole. This allows the barrier layer to come into direct contact with the first wafer exposed in the second through hole, avoiding the presence of increased contact resistance between the second metal layer and the first wafer (in this embodiment, between the BMV structures and the first substrate). Additionally, in the dry etching process performed on the first insulating dielectric layer for forming the first and second through holes, as the first through hole exposes only the first metal layer, and since the second through hole exposes only the first wafer, the bottom surfaces of the first and second through holes are both provided by single materials. In this way, when the first insulating dielectric layer is over-etched and the underlying structures is also slightly etched away, the problem of significant morphological inconsistency of the bottom surfaces of the first and second through holes resulting from greatly differing etching rates can be avoided. This allows the barrier layer to be continuous (without cracks or other defects) and thus have the ability to block fusion of the second metal layer with the first substrate, avoiding the occurrence of aluminum spiking in the case of the second metal layer being made of aluminum (Al). Further, the barrier layer is allowed to have a reduced thickness, which imparts lower contact resistance and can reduce cost. Furthermore, the occurrence of aluminum spiking can be avoided when an alloying process is employed after the formation of the second metal layer for removing any defect in the second metal layer.

The description presented above is merely that of a few preferred embodiments of the present invention and is not intended to limit the scope thereof in any sense. Any and all changes and modifications made by those of ordinary skill in the art based on the above teachings fall within the scope as defined in the appended claims.

1. A semiconductor device, comprising:
a first wafer;
a trench isolation ring formed in the first wafer, the trench isolation ring comprising a first metal layer;
a first insulating dielectric layer formed on a surface of the first wafer, the first insulating dielectric layer having at least one first through hole and at least one second through hole formed therein, the first through hole exposing a surface of the first metal layer, the second through hole exposing the surface of the first wafer;
a barrier layer formed at least on the surface of the first wafer exposed in the second through hole; and
a second metal layer formed on the first insulating dielectric layer, the second metal layer filling up the first through hole and the second through hole.

2. The semiconductor device of claim 1, wherein the first wafer comprises a substrate and a device layer formed on the substrate, wherein the trench isolation ring is formed in the substrate on a backside of the first wafer, and the first insulating dielectric layer is formed on a backside of the substrate.

3. The semiconductor device of claim 1, wherein the trench isolation ring further comprises a second insulating dielectric layer, the second insulating dielectric layer formed on side and bottom surfaces of a trench of the trench isolation ring in the first wafer, the trench filled up by the first metal layer.

4. The semiconductor device of claim 3, wherein each of the first insulating dielectric layer and the second insulating dielectric layer is made of a material comprising at least one of silicon oxide and a high-k dielectric with a dielectric constant k greater than 3.9, and wherein each of the first insulating dielectric layer and the second insulating dielectric layer is a single-layer structure or a structure consisting of at least two laminated layers.

5. The semiconductor device of claim 1, wherein the trench isolation ring has a rectangular, hexagonal or octagonal transverse cross-section.

6. The semiconductor device of claim 5, wherein the first through hole is located above a side and/or a corner of the trench isolation ring, and the second through hole is located above the first wafer at a location closer to a side and/or a corner of the trench isolation ring.

7. The semiconductor device of claim 1, further comprising a second wafer bonded to the first wafer.

8. A method of fabricating a semiconductor device, comprising:
providing a first wafer;
forming a trench isolation ring in the first wafer, the trench isolation ring comprising a first metal layer;
forming a first insulating dielectric layer on a surface of the first wafer, the first insulating dielectric layer having at least one first through hole and at least one second through hole formed therein, the first through hole exposing a surface of the first metal layer, the second through hole exposing the surface of the first wafer;
forming a barrier layer at least on the surface of the first wafer exposed in the second through hole; and
forming a second metal layer on the first insulating dielectric layer, the second metal layer filling up the first through hole and the second through hole.

9. The method of fabricating a semiconductor device of claim 8, wherein the first wafer comprises a substrate and a device layer formed on the substrate, wherein the trench isolation ring is formed in the substrate on a backside of the first wafer, and the first insulating dielectric layer is formed on a backside of the substrate.

10. The method of fabricating a semiconductor device of claim 8, wherein the trench isolation ring further comprises a second insulating dielectric layer, the second insulating dielectric layer formed on side and bottom surfaces of a trench of the trench isolation ring in the first wafer, the trench filled up by the first metal layer.

11. The method of fabricating a semiconductor device of claim 10, wherein each of the first insulating dielectric layer and the second insulating dielectric layer is made of a material comprising at least one of silicon oxide and a high-k dielectric with a dielectric constant k greater than 3.9, and wherein each of the first insulating dielectric layer and the second insulating dielectric layer is a single-layer structure or a structure consisting of at least two laminated layers.

12. The method of fabricating a semiconductor device of claim 8, wherein the trench isolation ring has a rectangular, hexagonal or octagonal transverse cross-section.

13. The method of fabricating a semiconductor device of claim 12, wherein the first through hole is located above a side and/or a corner of the trench isolation ring, and the second through hole is located above the first wafer at a location closer to a side and/or a corner of the trench isolation ring.

14. The method of fabricating a semiconductor device of claim 8, prior to the formation of the barrier layer at least on the surface of the first wafer exposed in the second through hole, the method of fabricating a semiconductor device further comprising performing a sputtering process on the surface of the first wafer exposed in the second through hole, thereby removing oxide attached to the surface of the first wafer.

15. The method of fabricating a semiconductor device of claim 8, before the trench isolation ring is formed in the first wafer, bonding layers are formed respectively on surface of the first wafer and a second wafer, and the first wafer is bonded to the second wafer through the bonding layers.

16. The semiconductor device of claim 1, wherein the trench isolation ring has a circular cross-section.

17. The method of fabricating a semiconductor device of claim 8, wherein the trench isolation ring has a circular cross-section.
